(19) United States
(12) Patent Application Publication
(10) Pub. No.: US 2008/0105987 A1
(43) Pub. Date: May 8, 2008

(54) SEMICONDUCTOR DEVICE HAVING INTERPOSER FORMED ON CHIP

(75) Inventor: Eiichi Hosomi, Kawasaki-shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/936,220

(22) Filed: Nov. 7, 2007

(30) Foreign Application Priority Data
Nov. 8, 2006 (JP) 2006-303015

(51) Int. Cl. H01L 23/52

(52) U.S. Cl. 257/784; 257/E23.141

(57) ABSTRACT

A semiconductor device having an interposer formed on a semiconductor chip is disclosed. The semiconductor chip includes a substrate which has external electrodes used for signal transfer or power supply with respect to the exterior and power supply pads arranged in an area on the substrate in which the external electrodes are not formed and connected to the external electrodes via wires on the main surface thereof. The interposer has a conductive layer arranged on part of the main surface of the semiconductor chip on which the power supply pads are not formed, connected to the semiconductor chip via connection pins and connected to the external electrodes for power supply via wires.

### CROSS-REFERENCE TO RELATED APPLICATIONS

This application is based upon and claims the benefit of priority from prior Japanese Patent Application No. 2006-303015, filed Nov. 8, 2006, the entire contents of which are incorporated herein by reference.

### BACKGROUND OF THE INVENTION

1. Field of the Invention

This invention relates to a semiconductor device having an interposer mounted on a chip by wire bonding.

2. Description of the Related Art

Semiconductor elements are required to be electrically connected to the exterior so that signals can be transferred with respect to or power can be supplied from the exterior. Like a wireless tag, signals may be transferred or power may be supplied in a contactless state in some cases, but signal transfer or power supply is generally performed by physically connecting electrodes on the chip to the exterior via conductive materials (conductive resin or metal such as Cu).

As one example of the connection method, it is considered to use a wire bonding technique. The wire bonding technique is a method for connecting electrodes on the chip to the external electrodes on the package substrate via thin gold wires.

In general, electrode pads on the chip are arranged on the peripheral portion of the chip. Therefore, the distance between a circuit in the central portion of the chip and the electrode pad on the chip becomes longer. As a result, if a device consuming much power is used, a voltage drop occurring between the electrode pad and the circuit becomes larger and the adequate performance cannot be attained in some cases.

Further, in the wire bonding technique, the electrode pads on the chip and the external electrodes are connected via gold wires with the length of several mm. So-called switching noise or di/dt noise is generated due to the inductance component of the wire. The noise also causes the performance of the semiconductor device to be lowered.

As a connecting method different from the wire bonding technique, a flip-chip connection method is provided (for example, refer to M. Suryakumar et al., “Dual Die Processor Package Design Optimization and Performance Evaluation”, IEEE, 2006 Electronic Components and Technology Conference, pp. 215 to 221). In the flip-chip connection method, fine projection electrodes (bumps) are formed on the chip electrodes to connect the chip to the package substrate. The projection electrodes can be formed in a matrix form on the front surface of the chip.

That is, in the flip-chip connection method, since terminals for supply of power can be formed on a desired circuit block, a voltage drop does not occur unlike the case of the wire bonding. Further, since the projection electrodes are extremely small (approximately 0.1 mm), di/dt noise caused thereby can almost be neglected. However, the cost for forming and assembling the projection electrodes becomes higher than that in the case of the wire bonding.

Therefore, it is desired to develop a method for solving the problem caused in the wire bonding method at low cost.

### BRIEF SUMMARY OF THE INVENTION

According to a first aspect of the present invention, there is provided a semiconductor device including a substrate which has an external electrode for signal transfer or power supply with respect to the exterior, a semiconductor chip having a power supply pad arranged in an area on the substrate in which the external electrode is not formed and connected to the external electrode via a wire on the main surface thereof, and an interposer having a conductive layer arranged on part of the main surface of the semiconductor chip, connected to the semiconductor chip via a connection pin and connected to the external electrode for power supply via wires.

According to a second aspect of the present invention, there is provided a semiconductor device including a substrate which has an external electrode for signal transfer or power supply with respect to the exterior, a semiconductor chip having a power supply pad arranged in an area on the substrate in which the external electrode is not formed and connected to the external electrode via a wire on the main surface thereof, and an interposer having a conductive layer arranged on part of the main surface of the semiconductor chip, connected to the semiconductor chip via a connection pin and used for power supply.

According to a third aspect of the present invention, there is provided a semiconductor device including a substrate which has an external electrode for signal transfer or power supply with respect to the exterior, a semiconductor chip arranged in an area on the substrate in which the external electrode is not formed, and an interposer having a conductive layer arranged to cover the main surface of the semiconductor chip, connected to the semiconductor chip via a connection pin and connected to the external electrode for power supply via a wire.

### BRIEF DESCRIPTION OF THE SEVERAL VIEWS OF THE DRAWING

FIG. 1 is a cross-sectional view showing an example of the structure of a semiconductor device according to a first embodiment of this invention;

FIG. 2 is a cross-sectional view showing another example of the structure of the semiconductor device according to the first embodiment of this invention;

FIG. 3 is a cross-sectional view showing still another example of the structure of the semiconductor device according to the first embodiment of this invention;

FIG. 4 is a cross-sectional view showing an example of the structure of a semiconductor device according to a second embodiment of this invention;

FIG. 5 is a cross-sectional view showing another example of the structure of the semiconductor device according to the second embodiment of this invention;

FIG. 6 is a cross-sectional view showing still another example of the structure of the semiconductor device according to the second embodiment of this invention;

FIG. 7 is a cross-sectional view showing an example of the structure of a semiconductor device according to a third embodiment of this invention;

FIG. 8 is a cross-sectional view showing another example of the structure of the semiconductor device according to the third embodiment of this invention; and

FIGS. 9A to 9C are cross-sectional views partially showing the states of the manufacturing steps of the semiconductor device according to the third embodiment of this invention.

### DETAILED DESCRIPTION OF THE INVENTION

### First Embodiment

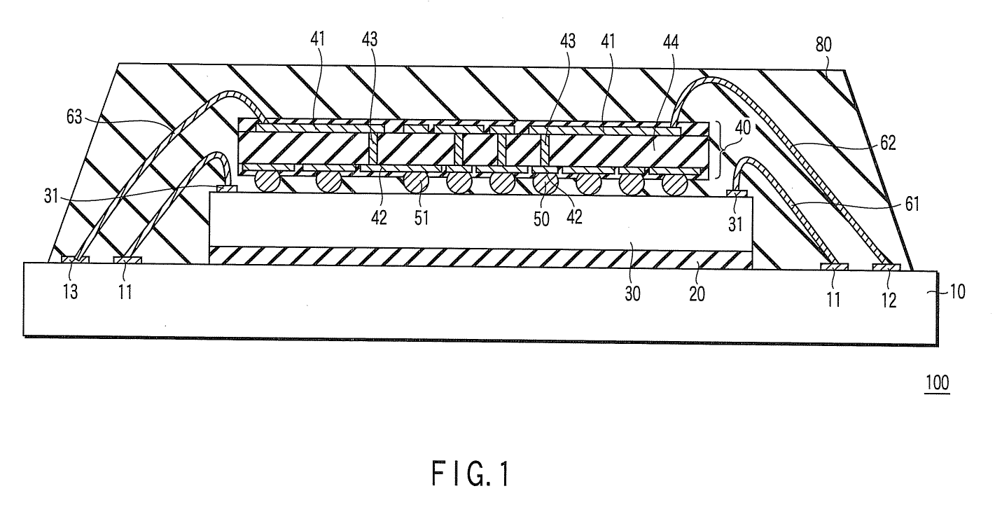

FIG. 1 shows an example of the structure of a semiconductor device 100 according to a first embodiment of this invention.

The semiconductor device 100 is configured to include a package substrate 10, die mount material (insulator) 20, semiconductor chip 30, connection pins 50, 51, interposer 40, gold wires 61, 62, 63, mold resin 80 and the like.

The die mount material 20 is formed on the package substrate 10 and the semiconductor chip 30 is mounted on the die mount material 20. External electrodes 11, 12, 13 are provided on the peripheral portion of the package substrate 10 and signal transfer or power supply with respect to the exterior via the external electrodes 11, 12, 13 is attained.

The external electrode 11 which is one of the external electrodes is electrically connected to a power supply pad 31 formed on the peripheral portion of the main surface of the semiconductor chip 30 via the gold wire 61 by wire bonding. A signal mainly transferred between the semiconductor chip 30 and the exterior passes through the gold wire 61.

In the central portion of the semiconductor chip 30 in which the power supply pads 31 are not provided, the interposer 40 is mounted. The interposer 40 and semiconductor chip 30 are electrically connected to each other via a large number of connection pins (conductors) 50, 51. For example, the connection pins 50, 51 are formed of a material such as solder, copper or conductive paste. The interposer 40 is electrically connected to the external electrodes 12, 13 via the gold wires 62, 63 by wire bonding. The connection wires 62, 63 between the interposer 40 and the package substrate 10 are used for power supply.

The interposer 40 includes a base member 44 which is an insulator, conductive layers 41, 42 arranged to sandwich the base member 44 in the vertical direction, and vias 43 which are used to electrically connect the conductive layers 41, 42 to each other. For example, the base member 44 is an organic substrate, ceramic substrate, semiconductor substrate formed of Si or the like and the conductive layers 41, 42 are formed of metal such as Cu, Al, Ag or the like.

In the present embodiment, power is directly supplied to a desired circuit block of the central portion of the semiconductor chip 30 via the interposer 40.

Specifically, for example, power supply voltage V_{dd} is applied to the semiconductor chip 30 via the gold wire 62, conductive layer 41, via 43, conductive layer 42 and connection pin 50. Further, ground potential GND is applied to the semiconductor chip 30 via the gold wire 63, conductive layer 41, via 43, conductive layer 42 and connection pin 51.

Therefore, the power supply voltage can be applied without substantially causing a voltage drop over the entire surface of the semiconductor chip 30 by adequately selecting a material whose resistance is sufficiently small as the conductive layers 41, 42 in the interposer 40. Since the film thickness of the wiring layer of the semiconductor chip 30 is approximately 1 to 2 μm, the voltage drop can be sufficiently suppressed if the total film thickness of the conductive layers 41, 42 is set to five to ten times the above film thickness, that is, approximately 10 μm or more. Further, since the film thickness of the conductive layer can be increased, the resistance and inductance thereof becomes small and the charging/discharging time of a decoupling capacitor 70 can be reduced.

The interposer 40 and semiconductor chip 30 are electrically connected to each other via a large number of connection pins (conductors), but in the case of the present embodiment, all of the connection pins are used for application of power supply voltage or grounding like the connection pins 50, 51.

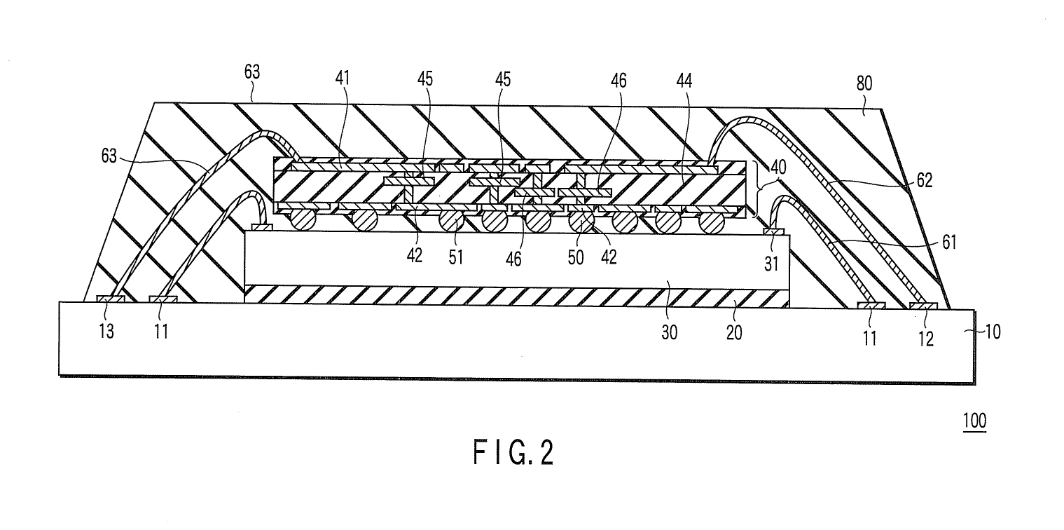

Further, as another example of the structure different from the structure of the present embodiment, as shown in FIG. 2, it is considered to additionally provide conductive layers 45, 46 in the interposer 40 to form a four-layered conductive layer structure. By thus increasing the number of conductive layers, the resistance can be reduced and the voltage drop can be further suppressed.

On the other hand, if the voltage drop can be sufficiently suppressed by, for example, satisfying the above film thickness condition, it is not always necessary to form the two conductive layers as shown in FIG. 1, and the structure in which a single conductive layer is provided and connected to the semiconductor chip 30 through a via and connection pin can be formed.

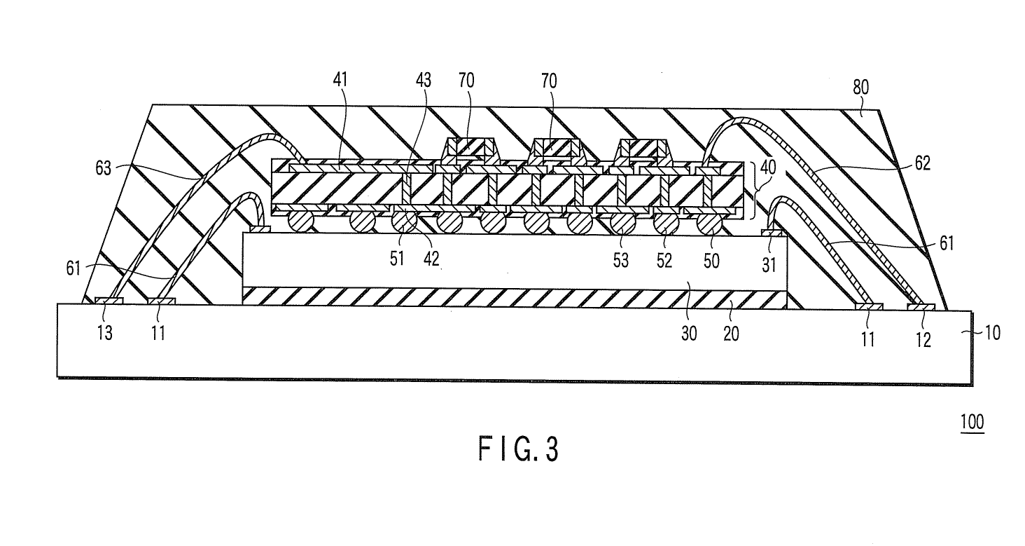

Further, in the present embodiment, as shown in FIG. 3, another charge supply device which is configured by the decoupling capacitor 70 or a power supply circuit of a DC/DC converter or the like to strengthen the power supply can be provided on the interposer 40.

Since the gold wires 62, 63 are generally several mm in length and have high-inductance components, noise called di/dt noise or switching noise is generally generated to make the power supply voltage unstable, thereby causing the power supply system to deteriorate.

By mounting an element such as the capacitor 70 on the interposer 40, a rapid lowering in the power supply voltage can be compensated for by supplying charge stored in the capacitor 70. Therefore, the power supply noise can be suppressed. Further, the same effect can be attained by mounting an active device such as a DC/DC converter instead of the decoupling capacitor 70 and supplying charge.

In this case, most of the connection pins between the interposer 40 and the semiconductor chip 30 are used for application of power supply voltage or grounding like the connection pins 50, 51, but the other connection pins such as the connection pins 52, 53 are used for supply of charge or transfer of a signal for power supply control when a DC/DC converter is mounted although not shown in the drawing and the applications thereof are limited to the above applications.

Further, in FIG. 3, of course, the conductive layer of the interposer 40 can be formed in the multi-layered form as shown in FIG. 2 to further suppress the voltage drop.

As described above, the semiconductor device 100 of the first embodiment can suppress the voltage drop by receiving power supply voltage via the interposer provided on the chip in the inexpensive package using wire bonding. Further, switching noise can also be suppressed by mounting the capacitor, power supply circuit or the like on the interposer. In addition, when charge supply device such as a DC/DC converter is provided instead of the decoupling capacitor 70, not only alternating current (AC) but also direct current (DC) can be handled.

That is, a semiconductor device having an excellent power supply characteristic equivalent to or superior to that of a package using flip-chip connection can be provided at low cost.

### Second Embodiment

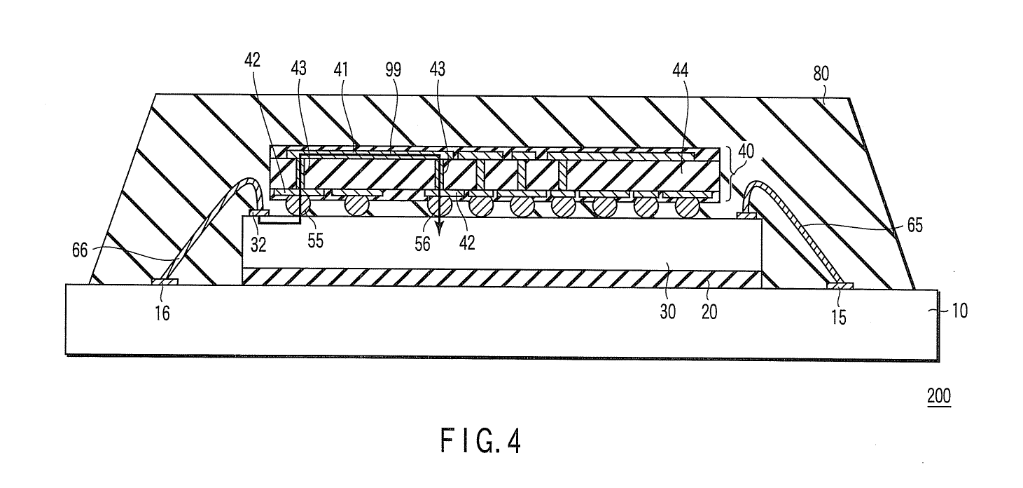

FIG. 4 shows an example of the structure of a semiconductor device 200 according to a second embodiment of this invention.

The semiconductor device 200 is configured to include a package substrate 10, die mount material (insulator) 20, semiconductor chip 30, connection pins 55, 56, interposer 40, gold wires 65, 66, mold resin 80 and the like.

The second embodiment is different from the first embodiment in that the interposer 40 and package substrate 10 are not directly connected by use of the gold wires.

Therefore, as the wires which connect the semiconductor chip 30 and package 10 to each other, the gold wire 66 for application of power supply voltage is required in addition to the gold wire 65 used for transferring a signal between the semiconductor chip 30 and the exterior.

Specifically, power supply voltage V_{dd} is applied via an external electrode 16 of FIG. 4, gold wire 66 and electrode pad 32 to the semiconductor chip 30 via the connection pin 55, conductive layer 42, via 43, conductive layer 41, via 43, conductive layer 42, and connection pin 56 in this order along an arrow 99. Although not shown in the drawing, the ground potential GND is also applied to the semiconductor chip 30. For example, the connection pins 55, 56 are formed of a material such as solder, copper or conductive paste.

Like the first embodiment, the power supply voltage can be applied without substantially causing a voltage drop over the entire surface of the semiconductor chip 30 by applying the power supply voltage via the interposer 40 and selecting a material whose resistance is sufficiently small as the conductive layers 41, 42 in the interposer 40.

Like the first embodiment, it is possible to sufficiently suppress the voltage drop if the total film thickness of the conductive layers 41, 42 is set to approximately 10 μm or more. Further, if the above condition is satisfied to sufficiently suppress the voltage drop, a conductive layer of a single layer can be used. Further, in the case of the present embodiment, all of the connection pins that connect the interposer 40 and semiconductor chip 30 to each other are used for application of power supply voltage or grounding like the connection pins 55, 56.

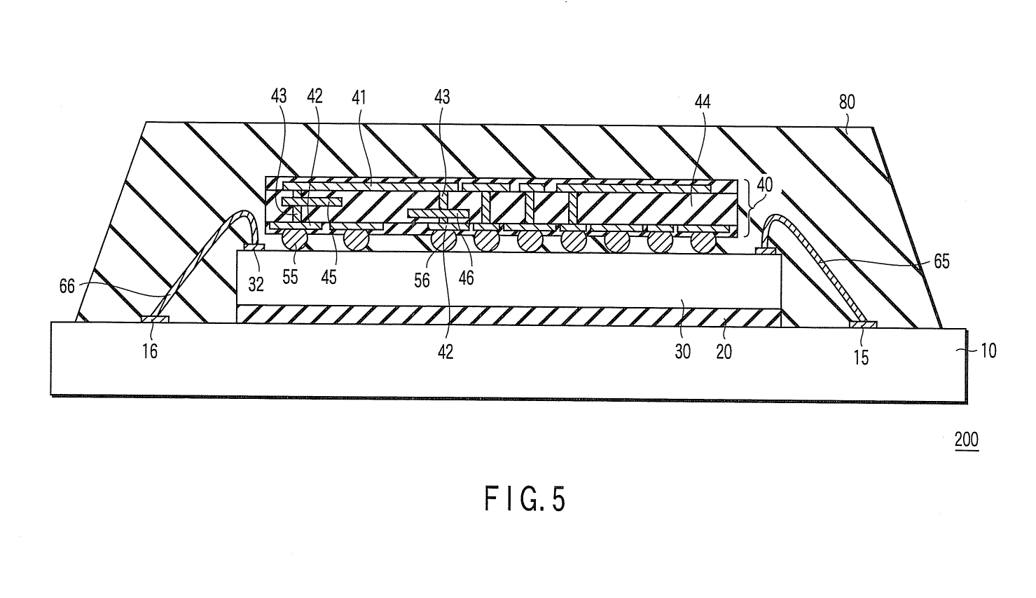

Further, as another example of the structure different from the structure of the present embodiment, as shown in FIG. 5, it is considered to additionally provide conductive layers 45, 46 in the interposer 40 to form a four-layered conductive layer structure and the voltage drop can be further suppressed.

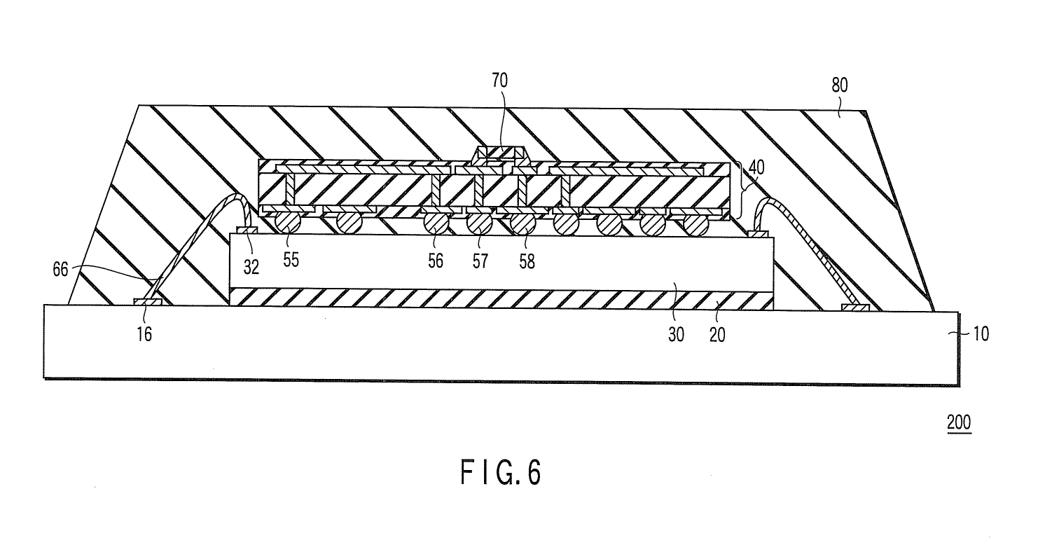

Further, in the present embodiment, as shown in FIG. 6, another charge supply device which is configured by the decoupling capacitor 70 or a power supply circuit of a DC/DC converter or the like to strengthen the power supply is mounted on the interposer 40 so that switching noise (di/dt noise) can be suppressed. When charge supply device is provided instead of the decoupling capacitor 70, not only alternating current (AC) but also direct current (DC) can be handled.

Also, in this case, most of the connection pins between the interposer 40 and the semiconductor chip 30 are used for application of power supply voltage or grounding like the connection pins 55, 56. However, the other connection pins such as the connection pins 57, 58 are used for supply of charge or supplying a signal for power supply control when a DC/DC converter is mounted although not shown in the drawing and the applications thereof are limited to the above applications.

Further, in FIG. 6, the conductive layer of the interposer 40 can be formed in the multi-layered form as shown in FIG. 5 to further suppress the voltage drop.

As described above, in the semiconductor device 200 of the present embodiment, the voltage drop can be suppressed by receiving power supply voltage via the interposer provided on the chip in an inexpensive package using wire bonding. Further, switching noise can also be suppressed by mounting the capacitor, power supply circuit or the like on the interposer.

That is, a semiconductor device having an excellent power supply characteristic equivalent to or superior to that of a package using flip-chip connection can be provided at low cost.

### Third Embodiment

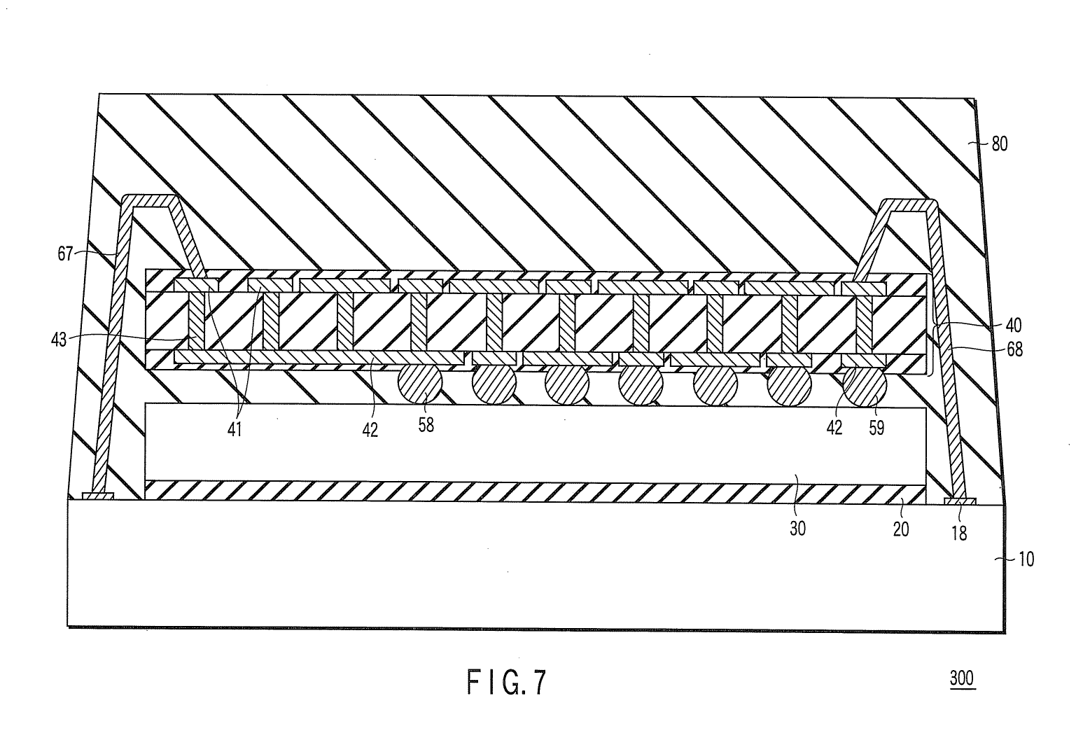

FIG. 7 shows an example of the structure of a semiconductor device 300 according to a third embodiment of this invention.

The semiconductor device 300 is configured to include a package substrate 10, die mount material (insulator) 20, semiconductor chip 30, connection pins 58, 59, interposer 40, gold wires 67, 68, mold resin 80 and the like.

The third embodiment is different from the first and second embodiments in that the lateral width and the length in the depth direction of the drawing of the interposer 40 are the same as those of the semiconductor chip 30 and the semiconductor chip 30 and package substrate 10 are not directly connected by use of the gold wires.

Therefore, for wire connection between the interposer 40 and the package 10, the gold wire 68 for transferring a signal between the semiconductor chip 30 and the exterior via the interposer 40 is required in addition to the gold wire 67 for application of power supply voltage.

Power supply voltage V_{dd} is applied to the semiconductor chip 30 via the gold wire 67, conductive layer 41, via 43, conductive layer 42 and connection pin 58. Although not shown in the drawing, the ground potential GND is also applied to the semiconductor chip 30. For example, the connection pins 58, 59 are formed of a material such as solder, copper or conductive paste.

Like the first embodiment, the power supply voltage can be applied without substantially causing a voltage drop over the entire surface of the semiconductor chip 30 by applying the power supply voltage via the interposer 40 and selecting a material whose resistance is sufficiently small as the conductive layers 41, 42 in the interposer 40.

It is possible to sufficiently suppress the voltage drop if the total film thickness of the conductive layers 41, 42 is set to approximately 10 μm or more. Further, if the above condition is satisfied to sufficiently suppress the voltage drop, a conductive layer of a single layer can be used. On the other hand, the conductive layer of the interposer 40 is formed in a multi-layered form to further suppress the voltage drop.

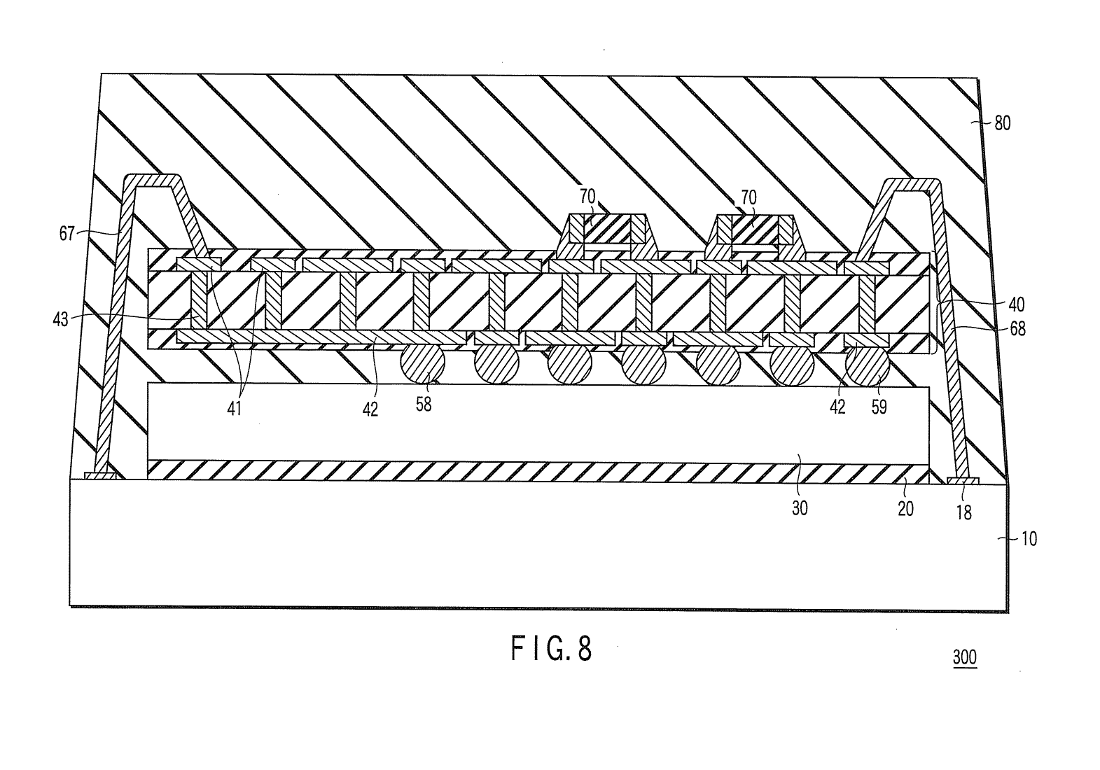

Further, in the present embodiment, as shown in FIG. 8, another charge supply device which is configured by the decoupling capacitor 70 or a power supply circuit of a DC/DC converter or the like to strengthen the power supply may be mounted on the interposer 40. As a result, switching noise (di/dt noise) can be suppressed. When charge supply device is provided instead of the decoupling capacitor 70, not only alternating current (AC) but also direct current (DC) can be handled. Also, in this case, the conductive layer of the interposer 40 can be formed in a multi-layered form so as to further suppress the voltage drop.

As described above, in the semiconductor device 300 of the third embodiment, the voltage drop can be suppressed by receiving power supply voltage via the interposer provided on the chip in an inexpensive package using wire bonding. Further, switching noise can also be suppressed by mounting the capacitor, power supply circuit or the like on the interposer. That is, a semiconductor device having an excellent power supply characteristic equivalent to or superior to that of a package using flip-chip connection can be provided at low cost.

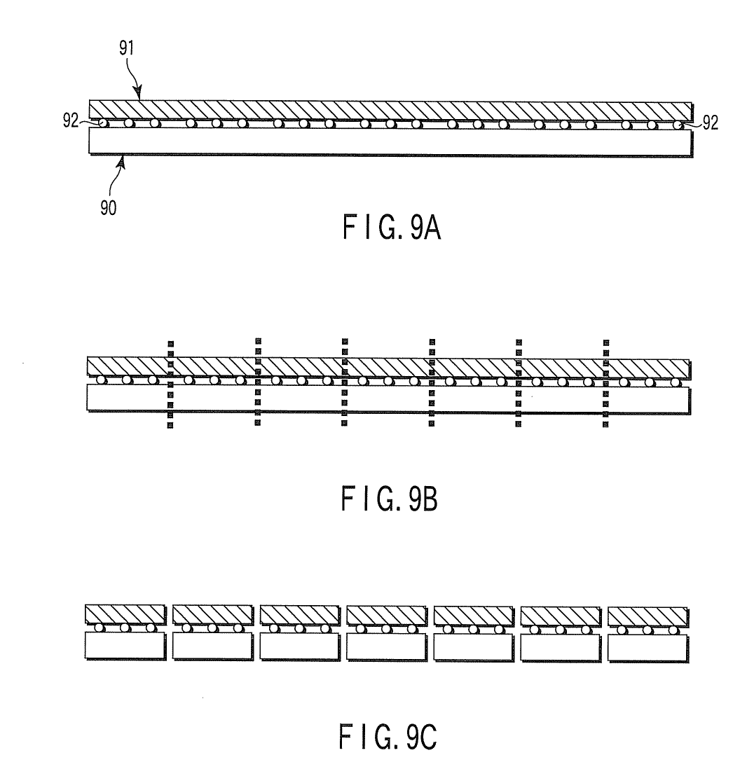

The lateral width and the length in the depth direction of the drawing of the semiconductor chip 30 of the semiconductor device 300 of the third embodiment are set equal to those of the interposer 40. Therefore, as shown in FIG. 9, a wafer can be cut apart, processed and formed in each chip unit in a state where a semiconductor wafer 90 and interposer 91 are laminated to each other with connection pins 92 disposed therebetween. That is, since the semiconductor device 300 of the present embodiment has the structure suitable for mass-production, an advantage that the manufacturing cost can be further lowered can be attained. Further, in FIG. 9, a resin material may be inserted into between the semiconductor wafer 90 and the interposer 91 in some cases in order to enhance the adhesion strength and reliability.

As described above, according to one aspect of this invention, a semiconductor device in which switching noise and a voltage drop caused by electrical connection of the semiconductor chip can be suppressed at low cost can be provided.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a substrate which has an external electrode used for one of signal transfer and power supply with respect to an exterior,
a semiconductor chip having a power supply pad arranged in an area on the substrate in which the external electrode is not formed and connected to the external electrode via a wire on a main surface thereof, and
an interposer having a conductive layer arranged on part of the main surface of the semiconductor chip, connected to the semiconductor chip via a connection pin and connected to the external electrode for power supply via a wire.

2. The semiconductor device according to claim 1, further comprising a charge supply device which is provided on the interposer to supply power to the semiconductor chip.

3. The semiconductor device according to claim 1, wherein the connection pin is used for at least one of supply of power supply voltage, grounding, charge supply and transfer of a signal for power supply control.

4. The semiconductor device according to claim 1, wherein the interposer includes an insulating base member and a via formed in the base member, the conductive layer is formed on one surface of the base member and in the via, the connection pin is formed in a position on another surface of the base member corresponding to the via and electrically connected to the conductive layer and the wire is connected to the conductive layer formed on the one surface of the base member.

5. The semiconductor device according to claim 1, wherein the interposer includes an insulating base member and a via formed in the base member, the conductive layer includes a first layer formed on one surface of the base member and a second layer formed on a surface of the base member opposite to the one surface and electrically connected to the first layer through the via, the connection pin is electrically connected to the second layer and the wire is electrically connected to the first layer.

6. The semiconductor device according to claim 1, wherein the interposer includes an insulating base member and a via formed in the base member, the conductive layer includes a first layer formed on one surface of the base member, a second layer formed on a surface of the base member opposite to the one surface and a third layer formed in the base member, electrically connected to the first layer through the via and electrically connected to the second layer through the via, the connection pin is electrically connected to the second layer and the wire is connected to the first layer.

7. A semiconductor device comprising:
a substrate which has an external electrode used for one of signal transfer and power supply with respect to an exterior,
a semiconductor chip having a power supply pad arranged in an area on the substrate in which the external electrode is not formed and connected to the external electrode via a wire on a main surface, and
an interposer having a conductive layer arranged on part of the main surface of the semiconductor chip, connected to the semiconductor chip via a connection pin and used for power supply.

8. The semiconductor device according to claim 7, further comprising a charge supply device which is provided on the interposer to supply power to the semiconductor chip.

9. The semiconductor device according to claim 7, wherein the connection pin is used for at least one of application of power supply voltage, grounding, charge supply and transfer of a signal for power supply control.

10. The semiconductor device according to claim 7, wherein the interposer includes an insulating base member and a via formed in the base member, the conductive layer is formed on one surface of the base member and in the via, and the connection pin is formed in a position on another surface of the base member corresponding to the via and electrically connected to the conductive layer.

11. The semiconductor device according to claim 7, wherein the interposer includes an insulating base member and a via formed in the base member, the conductive layer includes a first layer formed on one surface of the base member and a second layer formed on a surface of the base member opposite to the one surface and electrically connected to the first layer through the via, and the connection pin is electrically connected to the second layer.

12. The semiconductor device according to claim 11, wherein the connection pin is electrically connected to a different connection pin via the second layer, first layer and another second layer.

13. The semiconductor device according to claim 7, wherein the interposer includes an insulating base member and a via formed in the base member, the conductive layer includes a first layer formed on one surface of the base member, a second layer formed on a surface of the base member opposite to the one surface and a third layer formed in the base member, electrically connected to the first layer through the via and electrically connected to the second layer through the via, and the connection pin is electrically connected to the second layer.

14. The semiconductor device according to claim 13, wherein the connection pin is electrically connected to a different connection pin via the second layer, third layer, first layer, another third layer and another second layer.

15. A semiconductor device comprising:
a substrate which has an external electrode used for one of signal transfer and power supply with respect to an exterior,
a semiconductor chip arranged in an area on the substrate in which the external electrode is not formed, and
an interposer having a conductive layer arranged to cover a main surface of the semiconductor chip, connected to the semiconductor chip via a connection pin and connected to the external electrode for power supply via a wire.

16. The semiconductor device according to claim 15, further comprising a charge supply device which is provided on the interposer to supply power to the semiconductor chip.

17. The semiconductor device according to claim 15, wherein the connection pin is used for at least one of application of power supply voltage, grounding, charge supply and transfer of a signal for power supply control.

18. The semiconductor device according to claim 15, wherein the interposer includes an insulating base member and a via formed in the base member, the conductive layer is formed on one surface of the base member and in the via, the connection pin is formed in a position on another surface of the base member corresponding to the via and electrically connected to the conductive layer and the wire is connected to the conductive layer formed on the one surface of the base member.

19. The semiconductor device according to claim 15, wherein the interposer includes an insulating base member and a via formed in the base member, the conductive layer includes a first layer formed on one surface of the base member and a second layer formed on a surface of the base member opposite to the one surface and electrically connected to the first layer through the via, the connection pin is electrically connected to the second layer and the wire is connected to the first layer.

20. The semiconductor device according to claim 15, wherein the interposer includes an insulating base member and a via formed in the base member, the conductive layer includes a first layer formed on one surface of the base member, a second layer formed on a surface of the base member opposite to the one surface and a third layer formed in the base member, electrically connected to the first layer through the via and electrically connected to the second layer through the via, the connection pin is electrically connected to the second layer and the wire is connected to the first layer.
